(19) United States
(12) Patent Application Publication
(10) Pub. No.: US 2007/0252159 A1
(43) Pub. Date: Nov. 1, 2007

(54) Light emitting apparatus

(75) Inventors: Sean Chang, Taoyuan Hsien (TW); Yang-Lin Chen, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS INC.

(21) Appl. No.: 11/790,619

(22) Filed: Apr. 26, 2007

(30) Foreign Application Priority Data
Apr. 28, 2006 (TW) 095115251

(51) Int. Cl. H01L 33/00

(52) U.S. Cl. 257/79

(57) ABSTRACT

A light emitting apparatus includes a substrate, an insulating layer and at least one light emitting device. The insulating layer is disposed over the substrate and has a patterned area exposing at least a portion of the substrate. The light emitting device is disposed over the substrate and is located in the patterned area.

### CROSS REFERENCE TO RELATED APPLICATIONS

This Non-provisional application claims priority under 35 U.S.C. §119(a) on Patent Application No(s). 095115251 filed in Taiwan, Republic of China on Apr. 28, 2006, the entire contents of which are hereby incorporated by reference.

### BACKGROUND OF THE INVENTION

1. Field of Invention

The invention relates to a light emitting apparatus and in particular, to a light emitting apparatus having good heat dissipating efficiency.

2. Related Art

With the development of the optoelectronic industry, light emitting devices, such as LEDs (Light Emitting Diodes), have been widely and variously applied to display functions of electronic products.

Referring to FIG. 1, a conventional LED light emitting apparatus 1 includes a substrate 10, an insulating layer 11, a plurality of light emitting devices 12, a metal layer 13 and a package layer 14. The insulating layer 11 is disposed on the substrate 10. The light emitting devices 12, which are light emitting diodes (LEDs), are disposed on the insulating layer 11. The metal layer 13 is disposed on the insulating layer 11 and electrically connected to the light emitting devices 12 by wire bonding. The package layer 14 encapsulates the light emitting devices 12 to protect them from being influenced and damaged by mechanical factors, heat, moisture or other factors.

With the development of ever higher efficiency and ever higher luminance of the light emitting apparatus 1, the light emitting device 12 generates heat while operating, and the accumulated heat raises the temperature, influencing the light emitting efficiency and the lifetime of the light emitting device 12. However, the conventional light emitting device 12 is disposed on the insulating layer 11 with a poor heat dissipating property, and the heat generated by the light emitting device 12 can not be dissipated easily due to the airtight seal of the package layer 14. Thus, the heat dissipating problem becomes increasingly significant.

The conventional LED light emitting apparatus usually provides a heat dissipation structure for solving the above mentioned problem. For example, a heat sink can be disposed on the substrate 10 or attached to the bottom of the light emitting device 12. However, this method will complicate the packaging process and increase the production cost. Moreover, the adhesive for attaching the heat sink may cause thermal resistance and ageing issues.

Therefore, it is an important subject to provide a light emitting apparatus, which can be manufactured simply and have enhanced heat dissipating efficiency and good product reliability.

### SUMMARY OF THE INVENTION

In view of the foregoing, the invention is to provide a light emitting apparatus, which can be manufactured simply and have enhanced heat dissipating efficiency and good product reliability.

To achieve the above, the invention discloses a light emitting apparatus which includes a substrate, an insulating layer and at least one light emitting device. The insulating layer is disposed on the substrate and has a patterned area exposing at least a portion of the substrate. The light emitting device is disposed on the substrate and is located in the patterned area.

As mentioned above, the light emitting apparatus according to the invention is disposed on the large size substrate, which can be made of the material with good thermal conductivity, such as metal or alloys. Thus, the substrate can conduct and dissipate the heat generated by the light emitting device. By the superior heat dissipating effect, the light emitting apparatus can have longer lifetime. Compared with the prior art, the light emitting apparatus according to the invention is unnecessary to dispose and attach a heat sink. Therefore, it is possible to reduce the manufacturing cost, reduce the manufacturing time, simplify the manufacturing steps, avoid the problems of thermal resistance and ageing caused by the heat sink, and thus enhance the heat dissipating efficiency and the product reliability.

### BRIEF DESCRIPTION OF THE DRAWINGS

The invention will become more fully understood from the detailed description given herein below illustration only, and thus is not limitative of the present invention, and wherein:

FIG. 1 is a schematic illustration showing a conventional LED light emitting apparatus;

FIG. 2 is a schematic illustration showing light emitting apparatuses according to an embodiment of the invention; and

FIGS. 3 to 7 are schematic illustrations showing a light emitting apparatus according to another embodiment of the invention.

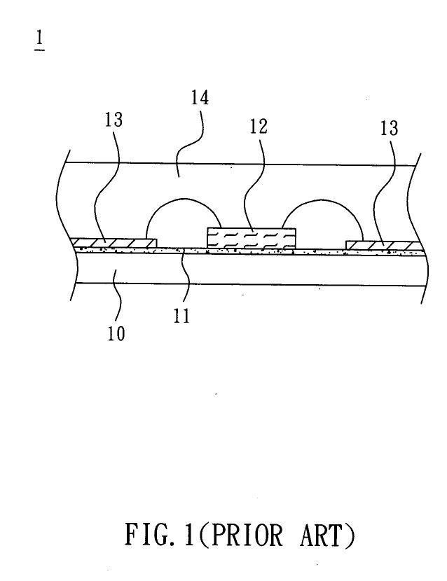

### DETAILED DESCRIPTION OF THE INVENTION

The present invention will be apparent from the following detailed description, which proceeds with reference to the accompanying drawings, wherein the same references relate to the same elements.

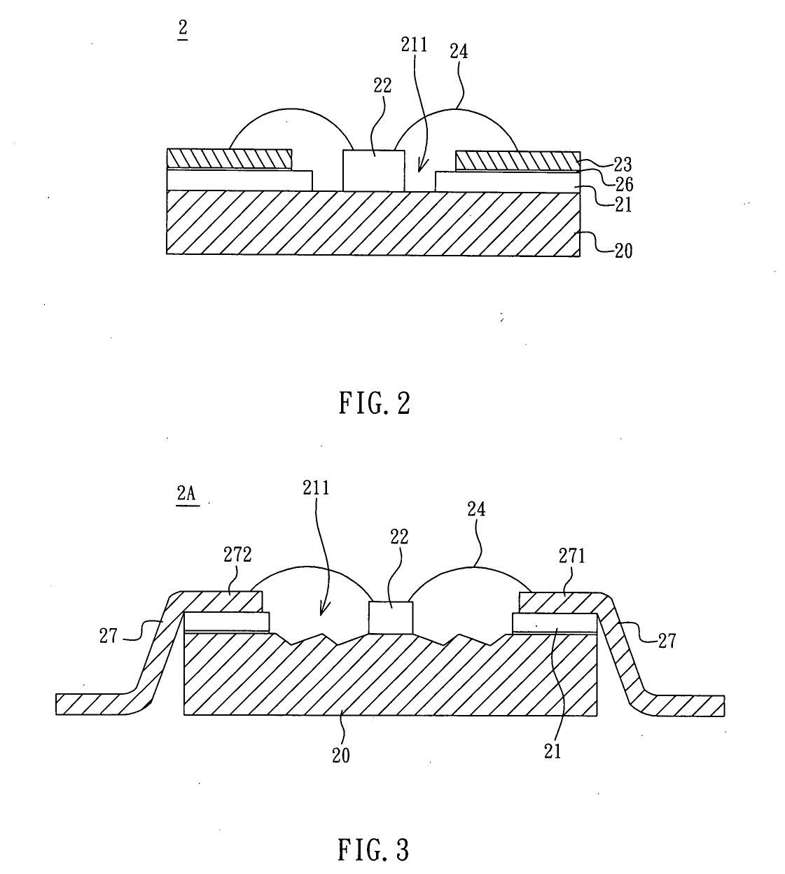

Referring to FIG. 2, a light emitting apparatus 2 according to an embodiment of the invention includes a substrate 20, an insulating layer 21 and at least one light emitting device 22.

In this embodiment, the material of the substrate 20 is composed of the material with good thermal conductivity for providing proper heat dissipating efficiency. Preferably, the material of the substrate 20 is made of copper, aluminum, magnesium, titanium and alloys thereof. Alternatively, the substrate can be composed of ceramic material or thermal conductive material. Furthermore, the substrate 20 can be a rigid substrate or a flexible substrate, and the substrate can have a plate, curve or saw shape.

The insulating layer 21 is disposed on the substrate 20 and has a patterned area 211 to expose at least a portion of the substrate 20. To form the patterned area 211, the insulating layer 21 is processed by a photolithography process or a screen printing process. The material of the insulating layer 21 can be made of aluminum oxide, magnesium oxide, titanium oxide, aluminum nitride, magnesium nitride, titanium nitride, aluminum carbide, magnesium carbide, titanium carbide, and compositions thereof. The insulating layer can be deposited by oxidizing, nitridizing or carbidizing the surface of the substrate 20. Alternatively, the insulating layer 21 can be formed on the substrate 20 by way of evaporating, sputtering, electroplating or CVD (Chemical Vapor Deposition). In more detailed, if the material of the substrate 20 is aluminum, magnesium, titanium or alloys thereof, the insulating layer 21 can be formed by oxidizing, nitridizing or carbidizing the surface of the substrate 20. If the substrate 20 is not made of aluminum, magnesium, titanium or alloys thereof, the insulating layer 21, which is composed of aluminum oxide, magnesium oxide or titanium oxide, can be formed on the substrate 20 by evaporating, sputtering, electroplating or CVD (Chemical Vapor Deposition).

The light emitting device 22 is disposed on the substrate 20 and is located within the patterned area 211. In this embodiment, the light emitting device 22 includes a first electrode, a second electrode and a light emitting layer (not shown). More specifically, the light emitting device 22 can be an LED (Light Emitting Diode), an LD (Laser Diode) or an OLED (Organic Light Emitter Diode).

The light emitting apparatus 2 of this embodiment further includes a metal layer 23 disposed on the insulating layer 21. The metal layer 23 is directly electrically connected to the first and second electrodes of the light emitting device 22 through at least one wire 24. The metal layer 23 can be used as a bonding pad electrically connecting to external circuits. The material of the metal layer 23 can be made of silver, gold, copper, aluminum and alloys thereof.

In order to dispose the metal layer 23 on the insulating layer 21, a connecting layer 26 can be formed between the metal layer 23 and the insulating layer 21. The connecting layer 26 has an adhesive property, or enables the metal layer 23 to be formed thereon. For example, the connecting layer 26 can be the initial layer for forming the metal layer 23 by way of plating. In this case, the connecting layer 26 is made of chromium, titanium, nickel and alloys thereof. In addition, the connecting layer 26 can be made of electrical conductive adhesive comprising copper, silver and tin.

As shown in FIG. 3, in a light emitting apparatus 2A according to the invention, the light emitting device 22 is electrically connected to an external circuit through a lead frame 27 disposed on the insulating layer 21. The lead frame 27 has a first electrode pin 271 and a second electrode pin 272, which may be respectively connected to the first electrode and the second electrode of the light emitting device 22 through the wires 24.

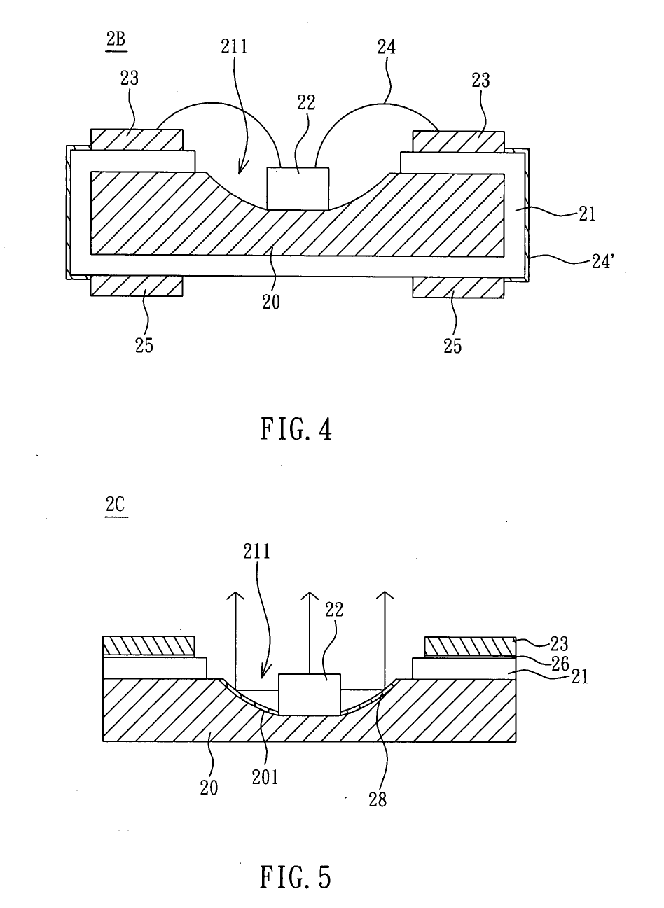

As shown in FIG. 4, in a light emitting apparatus 2B according to the invention, the insulating layer 21 can cover the surface of the substrate 20 except the portion exposed by the patterned area 211. The metal layer 23 can be disposed on the surface of the insulating layer 21 without covering the patterned area 211 and is electrically connected to the light emitting device 22. A plurality of connecting pads 25 are disposed at opposite sides underneath the substrate 20. The metal layers 23 disposed on the substrate 20 are electrically connected to the first and second electrodes of the light emitting device 22. The bonding pads 25 may be electrically connected to the metal layers 23 through wires or conductive layers 24′, respectively. To be noted, the above-mentioned connection by wire is for illustrations only and is not for limitations of the invention. For example, a U-shaped metal (not shown) may be used to clip one side of the light emitting apparatus 2B so as to construct the metal layer and bonding pads with the same functions of the previously mentioned elements. Thus, the bonding pads 25 underneath the insulating layer 21 can be electrically connected to the external circuit by way of SMT (Surface Mount Technology).

Referring to FIG. 5, in a lighting emitting apparatus 2C according to the invention, the substrate 20 further has a structure 201 for increasing the light emitting efficiency located corresponding to the patterned area 211. The structure 201 can reflect and concentrate the literal light outputted from the light emitting device 22. As shown in FIG. 5, the structure 201 for increasing the light emitting efficiency is a recess, and the light emitting device 22 is disposed in the recess. In this structure, the literal light outputted from the light emitting device 22 can be converged and emitted toward a display direction.

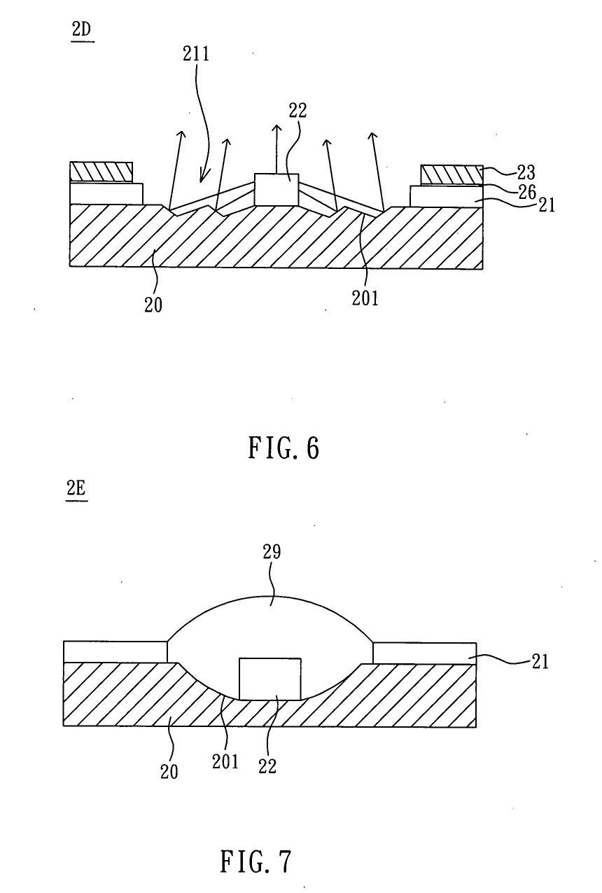

Alternatively, in a light emitting apparatus 2D according to the invention shown in FIG. 6, the structure 201 for increasing the light emitting efficiency can be an irregular structure, which is, for example, waveform-shaped or crepe-shaped. Of course, the structure 201 for increasing the light emitting efficiency can have a plurality of protrusions. The cross-section of the protrusions is polygonal, half-circular, circular or elliptic. According to this structure, the literal light outputted from the light emitting device 22 can be converged and emitted toward a display direction.

In addition, the light emitting apparatus 2 further includes a reflective layer 28 disposed on the structure 201 for enhancing the reflection and convergence of the lateral light of the light emitting device 22. As shown in FIG. 5, the reflective layer 28 is located within the patterned area 211 and is disposed around the light emitting device 22. The material of the reflective layer 28 includes silver, gold, nickel or aluminum.

Referring to FIG. 7, the light emitting apparatus 2E of the embodiment further includes a protective layer 29, which is disposed above the light emitting device 22 and is located corresponding to the patterned area 211. The protective layer 29 can protect the light emitting device 22. Meanwhile, the surface of the protective layer 29 may have the shape like a lens. The shape of the surface of the protective layer 29 can diverge or converge the light outputted from the light emitting device 22 to meet various display requirements.

In summary, in the light emitting apparatus according to the invention, the light emitting device is disposed on the large size substrate, which can be made of the material with good thermal conductivity, such as metal or alloys. Thus, the substrate can conduct and dissipate the heat generated by the light emitting device. By the superior heat dissipating effect, the light emitting apparatus can have longer lifetime. Compared with the prior art, the large-sized substrate has better heat dissipating effect without attached with a heat sink. Therefore, it is possible to reduce the manufacturing cost, reduce the manufacturing time, simplify the manufacturing steps, avoid the problems of thermal resistance and ageing caused by the heat sink, and thus enhance the heat dissipating efficiency and the product reliability.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A light emitting apparatus comprising:
a substrate;
an insulating layer disposed on the substrate and having a patterned area for exposing at least a portion of the substrate; and
at least one light emitting device disposed on the substrate and located in the patterned area.

2. The light emitting apparatus according to claim 1, wherein the substrate is made of copper, aluminum, magnesium, titanium, alloys thereof or ceramic.

3. The light emitting apparatus according to claim 1, wherein the insulating layer is made of oxide, nitride or carbide of aluminum, magnesium, or titanium.

4. The light emitting apparatus according to claim 1, wherein the insulating layer is formed by oxidizing, nitridizing or carbidizing a surface of the substrate, or by way of evaporating, sputtering, electroplating, chemical vapor deposition, photolithography process or a screen printing process.

5. The light emitting apparatus according to claim 1, wherein the insulating layer is made of a ceramic material or a thermal conductive material.

6. The light emitting apparatus according to claim 1, further comprising a reflective layer abutted on the light emitting device and disposed over the substrate, and the reflective layer is made of silver, gold, nickel or aluminum.

7. The light emitting apparatus according to claim 1, wherein the substrate is a rigid substrate or a flexible substrate, and the substrate is plate-shaped, curve-shaped or saw-shaped.

8. The light emitting apparatus according to claim 1, wherein the substrate has a surface corresponding to the patterned area, and the surface has an irregular structure with a plurality of protrusions, or a recess.

9. The light emitting apparatus according to claim 8, wherein the irregular structure is waveform-shaped or crepe-shaped.

10. The light emitting apparatus according to claim 8, wherein a cross-section of the protrusions is polygonal, half-circular, circular or elliptic.

11. The light emitting apparatus according to claim 8, further comprising a protective layer disposed above the patterned area, a surface of the protective layer is a lens for diverging or converging light emitted from the light emitting device.

12. The light emitting apparatus according to claim 1, further comprising a metal layer disposed on the insulating layer.

13. The light emitting apparatus according to claim 12, wherein the light emitting device and the metal layer are electrically connected through at least one wire or an electrical conducive layer.

14. The light emitting apparatus according to claim 12, further comprising a connecting layer disposed between the metal layer and the insulating layer so that the metal layer is disposed on the insulating layer, and material of the connecting layer is made of chromium, titanium, nickel, alloys of chromium, titanium and nickel, and electrical conductive adhesive comprising copper, silver and tin.

15. The light emitting apparatus according to claim 1, further comprising a lead frame having a first electrode pin and a second electrode pin, both of which are disposed on the insulating layer and electrically connected to the light emitting device.

16. The light emitting apparatus according to claim 15, wherein the light emitting device and the first electrode pin are electrically connected to each other through at least one wire, the light emitting device and the second electrode pin are electrically connected to each other through at least one wire.

17. The light emitting apparatus according to claim 1, wherein the insulating layer covers a surface of the substrate except the portion of the substrate exposed by the patterned area.

18. The light emitting apparatus according to claim 1, further comprising at least one bonding pad disposed on a surface of the insulating layer, wherein the light emitting device and the bonding pad are electrically connected through at least one wire, an electrical conducive layer, or a U-shaped metal.

19. The light emitting apparatus according to claim 1, wherein the light emitting device comprises a first electrode, a second electrode and a light emitting layer.

20. The light emitting apparatus according to claim 19, wherein the light emitting device is a light emitting diode, laser diode or organic lighting emitting diode.
